(19) United States
(12) Patent Application Publication
(10) Pub. No.: US 2022/0108874 A1
(43) Pub. Date: Apr. 7, 2022

(54) LOW CURRENT HIGH ION ENERGY PLASMA CONTROL SYSTEM

(71) Applicant: Applied Materials, Inc., Santa Clara, CA (US)

(72) Inventor: Vladimir Nagorny, Tracy, CA (US)

(73) Assignee: Applied Materials, Inc., Santa Clara, CA (US)

(21) Appl. No.: 17/063,824

(22) Filed: Oct. 6, 2020

(51) Int. Cl. H01J 37/32; H01L 21/02; C23C 16/509

(52) U.S. Cl. CPC H01J 37/32422; H01J 37/321; H01J 37/32715; H01J 2237/3321; H01L 21/02274; C23C 16/509; H01L 21/02164

(57) ABSTRACT

Exemplary semiconductor processing systems may include a processing chamber, an inductively coupled plasma (ICP) source disposed in or on the processing chamber, and a support configured to position a substrate. The support can be disposed at least partially within the processing chamber and can include a bias electrode. An ion screen may be disposed within the chamber to be above a substrate on the support. The ion screen is semitransparent to ions and electrons so that the density of plasma sustained above the ion screen is unaffected by RF bias power applied to the bias electrode. Plasma energy control is therefore accomplished while maintaining independence of plasma density from RF bias power so that high ion energy and low bias current may be afforded.

### TECHNICAL FIELD

The present technology relates to components and apparatuses for semiconductor manufacturing. More specifically, the present technology relates to plasma generating and control components and other semiconductor processing equipment.

### BACKGROUND

Integrated circuits are made possible by processes that produce intricately patterned material layers on substrate surfaces. Producing patterned material on a substrate requires controlled methods of film deposition and removal of exposed material. Chemical vapor deposition (“CVD”) is a gas-reaction process used in the semiconductor industry to form thin layers or films of desired materials such as SiO₂ on a substrate. High-density-plasma CVD processes use a reactive chemical gas along with physical ion generation through the use of an RF generated plasma to enhance the film deposition.

Recent developments in CVD have sparked interest in SiO₂ treatment with very low ion current and high ion energy to provide deep treatment prior to, or without growing the film. To provide such deep treatment, a relatively low RF source power is used with relatively high bias power. However, such a power configuration can result in a loss of independence between ion current and/or density and ion energy control provided by the source and bias powers. Further, plasma configuration changes made to accommodate differing requirements can lead to unusual non-uniformities in processed semiconductor substrates. Techniques for reducing these non-uniformities to an acceptable level can be complicated, difficult, and time-consuming to implement. Thus, there is a need for improved systems and methods that can be used to produce high-ion energy, well-controlled plasma while retaining the independence of plasma density from bias power to achieve high ion energy with relatively low bias power. These and other needs are addressed by the present technology.

### SUMMARY

Exemplary semiconductor processing systems may include a processing chamber, an inductively coupled plasma (ICP) source disposed in or on the processing chamber, and a support configured to position a substrate. The support can be disposed at least partially within the processing chamber and can include a bias electrode. A semitransparent ion screen is disposed within the chamber to be above and close to a substrate on the support. This attenuation allows an increase in a minimum source power, when plasma density sustained above the ion screen is high and is substantially unaffected by the RF bias power applied to the bias electrode, while the system provides a necessary ion flux to the substrate.

In one example, the ion screen is configured to allow 5% to 20% of ions and electrons to flow through the ion screen. In this example, the minimum source power of the system can be increased to between 500 W and 1000 W. Placing the ion screen close to the substrate, prevents the bias electric field applied between the ion screen and the substrate from sustaining the plasma in the area between the ion screen and the substrate and the RF bias power is almost completely spent on accelerating ions. In some embodiments, the ion screen is placed from 10 mm to 15 mm above the substrate.

In some embodiments, the ion screen includes a dielectric material. In some embodiments, the ion screen includes a conductor. A dielectric material may be placed on or around the conductor. The conductor may be configured to be grounded, floating, held at a set voltage, or some combination of these. In some embodiments, the ion screen includes holes arranged to be proximate to the substrate, wherein a ratio of a diameter of the holes to a thickness of the ion screen is from 1 to 4.

In some embodiments, a method of operating a semiconductor processing system includes using the ICP source to form plasma opposite the ion screen from the substrate within the chamber and applying RF bias voltage to the bias electrode. The space between the ion screen and the substrate behaves as an RF sheath, when most of the RF cycle time ions are accelerated toward the substrate, and for a short time electrons cross this gap and compensate the charge. The method includes linearly controlling ion energy based on the RF bias power while using the source power to control ion current.

Exemplary plasma control systems may include an ICP source, a bias electrode, and the ion screen configured to be disposed above a substrate between the ICP source and the bias electrode. In some embodiments, the system includes a variable voltage source connectable to a conductor of the ion screen. The variable voltage source is operable for setting and holding the conductor at a fixed DC voltage level.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary processing chamber according to some embodiments of the present technology.

FIG. 2 shows a schematic cross-sectional view of another exemplary processing chamber according to some embodiments of the present technology.

FIG. 3 shows a schematic cross-sectional view of an additional exemplary processing chamber according to some embodiments of the present technology.

FIG. 4 shows a schematic perspective view of an ion screen according to some embodiments of the present technology.

Several of the figures are included as schematics. It is to be understood that the figures are for illustrative purposes, and are not to be considered of scale unless specifically stated to be of scale. Additionally, being schematic in nature, the figures are provided to aid comprehension and may not include all aspects or information compared to realistic representations. The figures may include exaggerated material for illustrative purposes.

In the appended figures, similar components and/or features may have the same reference label. Further, various dimensions may be distinguished by a letter. If only a first reference label is used in the specification, the description is applicable to any one of the similar components.

### DETAILED DESCRIPTION

To provide deep treatment of a substrate, relatively low RF power, for example, about 100 W, is used to generate plasma while a relatively high power, for example, from 800-2000 W, is used as RF bias. Such a power configuration can result in a loss of independence between plasma current and/or density and therefore loss in ion energy control provided by the bias. Normally, inductively coupled plasma (ICP) source power controls plasma density (n) and ion current (Iᵢ) to the substrate, and bias power controls the ion energy (Wᵢ=P_{b}/Iᵢ). The loss of control occurs because, with low source power and high bias power, plasma density is no longer independent of bias power, but increases with it, leading to much less dependence of ion energy on bias power. For example, one would might need to more than double the RF bias power (800 W to 2000 W) to increase ion energy by only 25%. Further increase of ion energy requires even higher bias powers.

Plasma configuration changes made to a system using low source power and high bias power as described above to treat substrates with varying characteristics or to meet varying requirements can lead to unusual non-uniformities. These non-uniformities can lead to defects in films ultimately formed on the substrate. Techniques for reducing these non-uniformities to an acceptable level must be employed with each change. These techniques can be time consuming and/or complex, because fine plasma control at lower plasma densities with high bias power is quite difficult.

The present technology overcomes these challenges by utilizing an ion screen placed above the substrate. As one example, the ion screen may be a grounded but dielectric coated plate with openings arranged in a pattern to form a roughly circular grid portion above a semiconductor wafer being processed. The screen is thin enough and has openings of appropriate size and number to be semitransparent to ions and electrons. Plasma can be sustained above the screen using typical source power and the screen will keep the bias from significantly affecting plasma density. Plasma is not generated between the substrate and the screen, because of a short gap and low pressure. Plasma will stay at close to the ground potential, so that when the bias is negative, all the voltage is applied between the screen and the substrate, accelerating ions toward the wafer and redirecting electrons to the screen.

Compared to commonly used screens that attenuate ion/electron flux by about 1000 times or more to remove ions from the substrate, one example of this specially designed, ion screen is configured to allow 5% to 20% of ions and electrons to flow through the ion screen. This level of attenuation allows an increase in the minimum source power to between 500 W and 1000 W, when plasma density sustained above the ion screen is high and is unaffected by the RF bias power applied to the bias electrode, while the system provides a necessary ion flux to the wafer that otherwise could be obtained only with very low source power. Now, one can control this ion flux simply by varying the source power.

Another special characteristic of the ion screen is that it is configured for placement close to the substrate, so that the bias electric field applied between the screen and the substrate cannot sustain the plasma in that area and the RF bias power is almost completely spent on accelerating ions. In some embodiments the ion screen is placed from 10 mm to 15 mm above the substrate.

When the RF bias voltage changes polarity, the substrate reflects ions and absorbs electrons, compensating positive charge accumulated on the substrate during the negative part of the bias voltage waveform. Plasma energy control is straightforward and is accomplished while maintaining independence of plasma density from RF bias power. Therefore, high ion energy and low bias current may be afforded.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered so limited as to be for use with these specific deposition processes or chambers alone. The disclosure will discuss one possible system and chamber that may include lid stack components according to embodiments of the present technology before additional variations and adjustments to this system according to embodiments of the present technology are described.

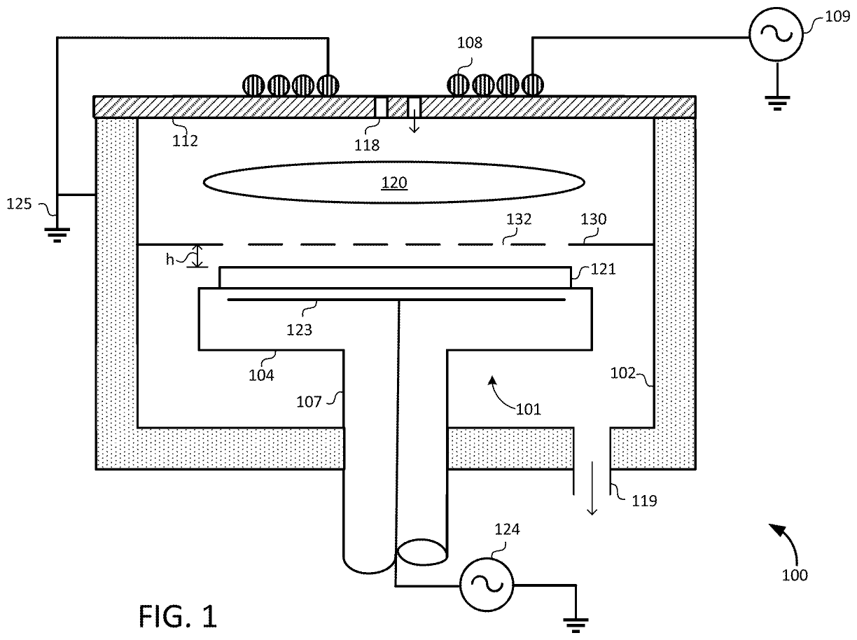

FIG. 1 shows a schematic cross-sectional view of an exemplary semiconductor processing system according to some embodiments of the present technology. As shown, the processing system 100 includes a chamber 102 suitable for processing a substrate 121. The processing system 100 may be used for various plasma processes. For example, the processing system 100 may be used to perform dry etching with one or more etching agents. The processing system may be used for ignition of plasma from a precursor CₓF_{y} (where x and y represent values for known compounds), O₂, NF₃, Ar, He, H₂, or combinations thereof. In another example, the processing chamber 100 may be used for a plasma-enhanced chemical vapor deposition (PECVD) process with one or more precursors.

The system includes a support 101. The support 101 in this example is an electrostatic chuck including support stem 107 and chuck body 104. While a portion of the support stem may protrude from the chamber, the electrostatic chuck is at least partially contained within the processing chamber during operation. The support includes a bias electrode 123. Bias is provided by an RF generator 124. An additional voltage may be applied to electrode 123 to provide chucking force. An ICP electrode 108 is provided, possibly as a portion of a lid assembly (not shown) for the processing chamber. Gas-in ports 118 and a gas-out port 119 are also provided. The electrode 108 is coupled to a source of electric power, such as RF generator 109. A return path for RF current through electrode 108 is provided by ground terminal 125, which also provides a ground connection for chamber 102. The electrode 108 and its power source serve as an ICP source. RF power to the electrode produces plasma 120 within the chamber 102.

The support 101 may be coupled to a lift mechanism (not shown) through support stem 107, which extends through a bottom surface of the chamber body 102. The lift mechanism may be flexibly sealed to the chamber body 102 by a bellows that prevents vacuum leakage from around the support stem 107. The lift mechanism may allow the support stem 107 to be moved vertically within the chamber body 102 between a transfer position and/or a number of process positions to place the substrate 121 in proximity to the electrode 108. An ion screen 130 is installed in the processing chamber 102. The ion screen 130 is thin enough and has openings 132 of appropriate size and number proximate to substrate 121 so that the ion screen 130 is semitransparent to ions and electrons. The chamber and ion screen are configured so that a spacing h between the bottom surface of the ion screen and the top surface of substrate 121 is from 10 mm to 15 mm, taking into account any anticipated movement of the support 101 that is caused in order to position substrate 121. Movement of the support may be accommodated by providing for simultaneous movement of the ion screen. In the example of FIG. 1, ion screen 130 is made of a conductor or a dielectric material and is floating relative to ground and voltages present in semiconductor processing system 100.

The term “semitransparent” as used herein refers to a screen that allows measurable ion transmission to the substrate, but that keeps ion transmission low enough to allow the minimum ICP source power to be above 500 W while maintaining a linear response of ion energy to bias power during normal operation of the system. The precise minimum and maximum transmission values that work can vary with system design. In some cases, for example, the allowed flow rate to provide acceptable results could be from as little as 1% to as much as 40%.

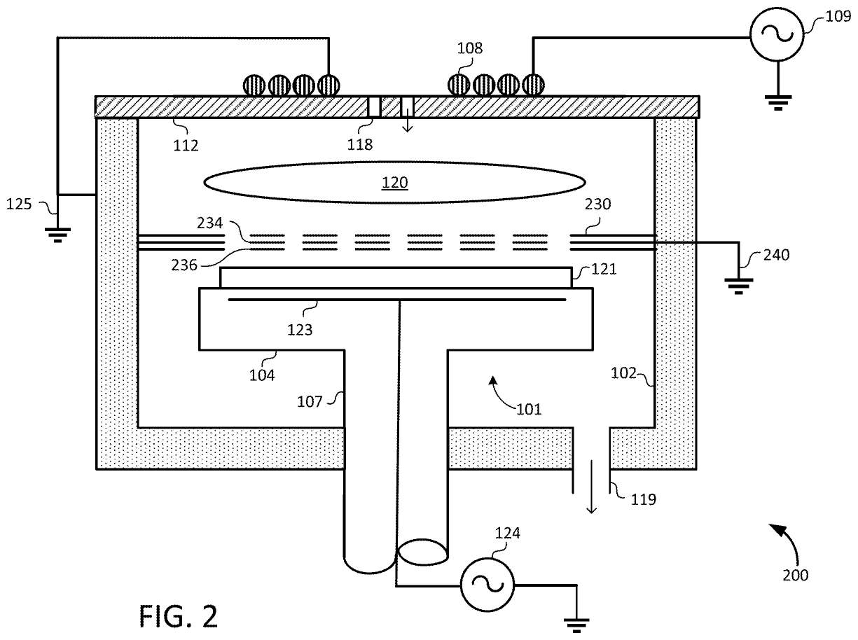

FIG. 2 shows a schematic cross-sectional view of another exemplary processing chamber according to some embodiments of the present technology. As shown, the processing system 200 includes the chamber 102 suitable for processing the substrate 121. The processing system 200 may be used for various plasma processes. The system includes the processing chamber 102 and the support 101. The support includes the bias electrode 123. Bias is provided by RF generator 124. The ICP electrode 108 is provided, as is the gas distributor plate 112. The electrode 108 is coupled to RF generator 109. A return path for RF current through electrode 108 is provided by ground terminal 125, which also provides a ground connection for the chamber 102.

In FIG. 2, an ion screen 230 is installed in the processing chamber 102. The ion screen 230 is thin enough and has openings of appropriate size and number proximate to substrate 121 so that the ion screen 230 is semitransparent to ions and electrons. The chamber and ion screen are configured so that the spacing between the bottom surface of the ion screen and the top surface of substrate 121 is from 10 mm to 15 mm. In the example of FIG. 2, ion screen 230 includes conductor 234, which is coated or covered on both sides by dielectric material 236. Conductor 234 is grounded by ground terminal 240.

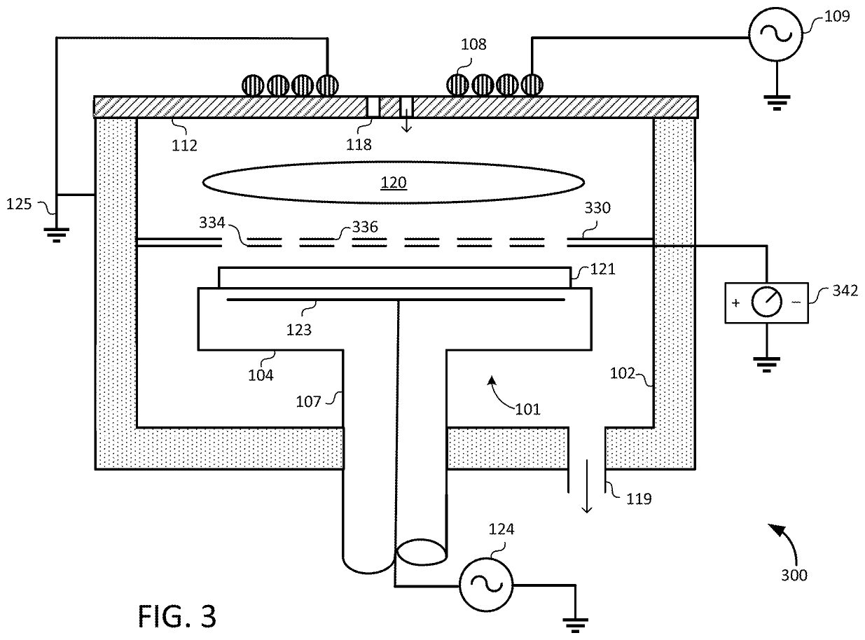

FIG. 3 shows a schematic cross-sectional view of an additional exemplary processing chamber according to some embodiments of the present technology. As shown, the processing system 200 includes the chamber 102 suitable for processing the substrate 121. The processing system 200 may be used for various plasma processes. The system includes the processing chamber 102 and the support 101. The support includes the bias electrode 123. Bias is provided by RF generator 124. The ICP electrode 108 is provided, as is the gas distributor plate 112. The electrode 108 is coupled to RF generator 109. A return path for RF current through electrode 108 is provided by ground terminal 125, which also provides a ground connection for the chamber 102.

In FIG. 3, an ion screen 330 is installed in the processing chamber 102. The ion screen 330 is thin enough and has openings of appropriate size and number proximate to substrate 121 so that the ion screen 330 is semitransparent to ions and electrons. The chamber and ion screen are configured so that the spacing between the bottom surface of the ion screen and the top surface of substrate 121 is from 10 mm to 15 mm. In the example of FIG. 3, ion screen 330 includes conductor 334, which is coated or covered on the top surface by dielectric material 336. Conductor 334 of ion screen 330 is connected to a variable voltage source 342. The variable voltage source operable to hold the conductor at a fixed, DC voltage level, which can be adjusted to achieve desired results. Thus, the grid portion between the substrate and the plasma can be set to any potential within a range achievable by the variable voltage source in order to maintain tighter control over the plasma flow.

The ICP source shown in the above-described figures is an example. Any type of plasma generating hardware can be used and the frequency range can vary. Different configurations of electrodes can be used, as can different frequency ranges. As examples, RF generator 109 may include a high frequency radio frequency (HFRF) power source, a low frequency radio frequency (LFRF) power source, a microwave source, or some combination of these.

Any of the three ion screen structures shown in the above figures can be used in any of the depicted systems. As examples, the ion screen including a conductor and dielectric material on both sides can be floating or connected to variable voltage source 342. The ion screen including a conductor and dielectric material on one side can be floating or grounded. The single-layer ion screen, if conductive, can be grounded or connected to variable voltage source 342. In addition to a single ion screen with various options for coatings and layers, multiple ion screens can be used together. For example two, substantially parallel ion screens can be used. A variable voltage source can optionally be used to maintain a DC potential between the two screens. The term substantially in this context refers to positioning the ion screens to be parallel within typical mechanical tolerances of the system. The same applies to the ion screen, which the examples discussed above, is positioned to be substantially parallel to the top surface of the substrate.

The chamber walls are typically made of conductive material, but can be coated inside with dielectric material. In the case where the ion screen is a dielectric coated conductive plate, either the same or different dielectric material can be used on the chamber walls and the plate. In all of the above examples, the ion screen is semitransparent to ions and electrons such that from 5% to 20% of ions and electrons flow through the grid portion of the ion screen. Thus, plasma can be sustained above the ion screen using typical source power of from 500 W to 1000 W, and bias will not affect plasma density. No significant plasma is generated between the substrate and the ion screen. If the ion screen uses a grounded conductor, plasma will stay at close to ground potential. Electrons build charge on the substrate side of the grid portion of the ion screen and in the openings, limiting ion current so that when the RF bias voltage is negative, all the bias voltage is applied between the screen and the substrate, accelerating ions toward the substrate and redirecting electrons to the screen. When the RF bias voltage changes polarity, the substrate reflects ions and absorbs electrons, compensating positive charge accumulated on the substrate during the negative part of the bias voltage waveform.

Since ion current is completely controlled by the plasma above the ion screen, the size of the ion accelerating region stays constant at the grid-substrate distance h; the ion energy depends on the RF bias power linearly, and one does not have to use high bias power to achieve high ion energy. The energy control is straightforward and is accomplished while maintaining independence of plasma density from RF bias power. Therefore, high ion energy and low bias current (and power) can be maintained. Uniformity of the processed substrate is improved because the plasma profile is flat above the grid portion of the ion screen, and grid portion is smaller than the chamber diameter.

The ion screen is relatively close to the substrate. In the examples above, the bottom of the ion screen is from 10 mm to 15 mm from the top of the substrate. This distance may vary more in some designs, for example, from 10 mm to 20 mm or from 10 mm to 25 mm. When the semiconductor processing system is in operation, the ion screen is substantially coextensive with the chamber. Thus, the portion of the ion screen that is outside the grid spans close enough to the walls to prevent plasma penetration to the bottom of the chamber outside of the substrate, but far enough from the walls to allow free movement of the ion screen with the substrate given the mechanical and thermal tolerances of the various parts that make up the system. Movement and placement of the ion screen can be accomplished manually, or the ion screen can be attached to a structure that lifts the ion screen up or down synchronously with lift pin movement for loading and unloading the substrate.

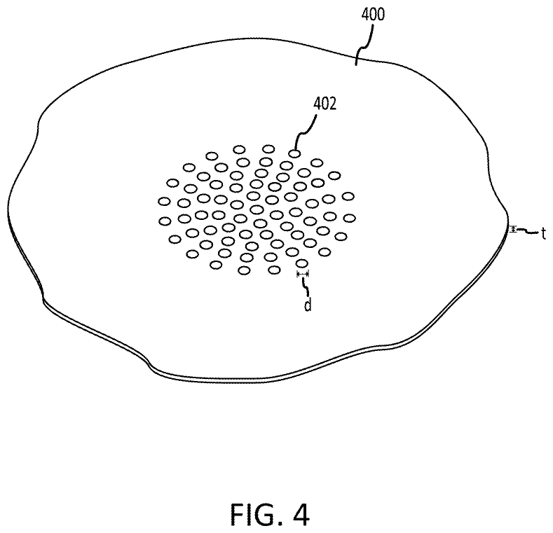

FIG. 4 shows a schematic perspective view of an ion screen according to some embodiments of the present technology. Ion screen 400 is shown enlarged, and with exaggerated or underrepresented dimensions for clarity. In actuality, the ion screen is thin enough and has openings of appropriate size and number to be semitransparent to ions and electrons. Ion screen 400 extends to be substantially coextensive with the walls of a semiconductor processing chamber. Ion screen 400 includes holes 402, positioned to be proximate to a semiconductor substrate being processed. By “proximate” to the substrate, what is meant is that the holes are confined to the area above the substrate's surface. The holes therefore form a grid portion of the ion screen, while the portions outside the grid portion extend towards the chamber walls. In some examples, the holes 402 are formed so that the ratio of their diameter d to the thickness t of the ion screen is greater than 1, for example, between 1 and 10. In another example, the ratio of diameter d to the thickness t of the ion screen is between 1 and 4. In some embodiments, the total thickness of the screen is between 2 mm and 12 mm. In some embodiments, the thickness of the screen is between 5 mm and 7 mm. The holes would typically be made to be as densely packed as possible while maintaining appropriate structural integrity of the ion screen. The holes can be formed in shapes other than the round shapes shown for holes 402, for example, square, hexagonal, oval, or any other geometric shape as long as the relationship of the area of the ion screen subtended by holes relative to the thickness of the ion screen is maintained.

As one example, the ion screen 400 may be a conductive but dielectric coated plate with openings 402 arranged in a pattern to form a roughly circular grid portion above the substrate being processed. As another example, the ion screen may be a metal with dielectric material on only one side, such as ion screen 330, which has dielectric material on only the top side. Ion screen 400 may also be a unitary plate made of either conductive material or dielectric material. A bare metal ion screen will provide the same advantages as a dielectric coated screen if bias current is controlled and measurements are made to ensure that ion current to the substrate is balanced and that the substrate remains neutral. And ion screen made of solid, dielectric material can also serve. In this case, the ion screen changes the capacitance between the substrate and the plasma. Again, bias current should be controlled to maintain neutrality of the substrate and balanced ion current flow.

A metal plate used to make ion screen 400 should be made from material that is safe in terms of corrosion or oxidation that may occur in a semiconductor processing environment. For example, aluminum can be used as a conductive material for the ion screen. Examples of dielectric material that can be used include quartz, SiO₂, or ceramic. The material should be selected so that if both metal and dielectric material are used, the coefficients of expansion are approximately the same in order to minimize cracking or deformation of the ion screen caused by temperature changes in the chamber.

When an ion screen is placed in a semiconductor processing chamber described with respect to any of FIGS. 1-3, so as to be close to but above the surface of a substrate being processed. The substrate is processed by using the ICP source electrode 108 to form plasma 120 in the chamber opposite the ion screen from the substrate 121. The RF bias voltage is applied to the bias electrode 123. The space between the ion screen and the substrate behaves as an RF sheath, when most of the RF cycle time ions are accelerated toward the substrate, and for a short time electrons cross this gap and compensate the charge. The system alternatively accelerates ions from the plasma toward the substrate while reflecting electrons from the substrate to the ion screen, and reflects ions from the substrate to the ion screen. The flow changes each time the RF bias voltage from RF generator 124 changes polarity. When the ions are reflected from the substrate to the ion screen, they compensate positive charge accumulated in or on the substrate. As the ion flow is managed at least in part by the ion screen, the ion energy is linearly controlled based on the RF bias voltage while using the plasma to control the ion current.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “an electrode” includes multiple such electrodes, and reference to “the support” includes reference to one or more supports and equivalents thereof known to those skilled in the art, and so forth.

Also, the words “comprise(s)”, “comprising”, “contain(s)”, “contained”, “include(s)”, and “including”, when used in this specification and in the following claims, are intended to specify the presence of stated features, integers, components, or operations, but they do not preclude the presence or addition of one or more other features, integers, components, operations, acts, or groups. The words “coupled”, “connected”, “connectable”, “disposed” and similar terms may refer to a direct connection or placement between components, or a connection or placement with or among intervening components. Terms such as “above”, “below”, “top”, and “bottom” are meant to refer to relative positions when observing the figures in a normal orientation and do not necessarily imply actual positioning in a physical system.

What is claimed is:

1. A semiconductor processing system comprising:
a processing chamber;
an inductively coupled plasma (ICP) source disposed in or on the processing chamber;
a support configured to position a substrate, the support disposed at least partially within the processing chamber and including a bias electrode; and
an ion screen disposed within the processing chamber to be above a substrate on the support, the ion screen being semitransparent to ions and electrons so that a density of plasma sustained above the ion screen is unaffected by RF bias power applied to the bias electrode.

2. The semiconductor processing system of claim 1, wherein the ion screen comprises a dielectric material.

3. The semiconductor processing system of claim 1, wherein the ion screen comprises a conductor.

4. The semiconductor processing system of claim 3, wherein the ion screen further comprises a dielectric material disposed above or around the conductor.

5. The semiconductor processing system of claim 3, wherein the ion screen is configured for the conductor to be at least one of grounded, floating, or held at a set voltage.

6. The semiconductor processing system of claim 5, wherein the ion screen defines a plurality of holes arranged to be proximate to the substrate, wherein a ratio of a diameter of the holes to a thickness of the ion screen is from 1 to 4.

7. The semiconductor processing system of claim 1, wherein the ion screen is configured to allow ion and electron flow from 5% to 20% when an ICP power is between 500 W and 1000 W and the ion screen is from 10 mm to 15 mm above the substrate.

8. A method of processing a semiconductor substrate, the method comprising:
using an ICP source to form plasma opposite an ion screen from a substrate within the processing chamber;
applying an RF bias voltage to a bias electrode;
alternatively:
accelerating ions from the plasma towards the substrate using the ion screen and the RF bias voltage while reflecting electrons from the substrate to the ion screen; and
reflecting ions from the substrate to the ion screen to compensate positive charge accumulated in or on the substrate; and
linearly controlling ion energy based on the RF bias voltage while using the plasma to control ion current.

9. The method of claim 8, wherein the ion screen comprises a dielectric material.

10. The method of claim 8, wherein the ion screen comprises dielectric material on or around conductive material.

11. The method of claim 10, wherein the ion screen comprises a plurality of holes, wherein a ratio of a diameter of the holes to a thickness of the ion screen is from 1 to 4.

12. The method of claim 8, wherein the ion screen is from 10 mm to 15 mm above a surface of the substrate on the support.

13. The method of claim 12, wherein the ion screen allows ion and electron flow from 5% to 20%.

14. A plasma control system for semiconductor processing, the plasma control system comprising:
an inductively coupled plasma (ICP) source;
a bias electrode; and
an ion screen configured to be disposed above a substrate between the ICP source and the bias electrode, the ion screen further configured to allow ion and electron flow of 5% to 20% while a plasma is sustained above the ion screen.

15. The plasma control system of claim 14, wherein the ion screen comprises a dielectric material.

16. The plasma control system of claim 14, wherein the ion screen comprises a conductor.

17. The plasma control system of claim 16, wherein the ion screen further comprises a dielectric material disposed above or around the conductor.

18. The plasma control system of claim 16, wherein the conductor is configurable to be at least one of grounded or floating.

19. The plasma control system of claim 16 further comprising a variable voltage source connectable to the conductor, the variable voltage source operable to hold the conductor at a fixed DC voltage level.

20. The plasma control system of claim 14, wherein the ion screen defines a plurality of holes arranged to be proximate to the substrate, wherein a ratio of a diameter of the holes to a thickness of the ion screen is from 1 to 4.
